(19) United States
(12) Patent Application Publication
(10) Pub. No.: US 2002/0045994 A1
(43) Pub. Date: Apr. 18, 2002

(54) Remote signal analyzer, classifier, and database generator

(76) Inventor: Thomas G. Hampton, Dorchester, MA (US)

Correspondence Address: FOLEY, HOAG & ELIOT, LLP, PATENT GROUP, ONE POST OFFICE SQUARE, BOSTON, MA, 02109, US

(21) Appl. No.: 09/977,820

(22) Filed: Oct. 15, 2001

Related U.S. Application Data
(60) Provisional application No. 60/240,590, filed on Oct. 13, 2000.

(51) Int. Cl. G01R 13/00; G06F 19/00

(52) U.S. Cl. 702/66

(57) ABSTRACT

Methods and systems for remotely analyzing signals through a communications network. In one embodiment, the methods and systems may be adapted to a subscriber medical research facility wherein data is collected from samples for further analysis. The methods and systems provide a graphical user interface to allow the subscriber to collect data through a data acquisition system, classify the waveforms, select appropriate analysis algorithms and results, and further choose algorithm parameters. The data and all subscriber entered options may be transmitted through a communications system to a remote analysis engine that may be coupled to a database. The remote analysis engine may analyze the data in accordance with the analysis options. In some embodiments, the analysis results may be obtained or further incorporated into the database. The analysis results may also be transmitted through the communications network, to the subscriber for further review and editing by the subscriber. In one embodiment, the communications network is the internet.

### BACKGROUND OF THE INVENTION

(1) Field of the Invention

The present invention relates generally to signal processing, and more particularly to methods and systems for a remote signal processor.

(2) Description of the Prior Art

The seemingly ever-increasing computational power of computers makes the electronic devices indispensable in nearly all computationally intensive environments. One such environment is a medical research laboratory. Whether the laboratory is academic or in industry, there is a large demand for computational power, particularly with respect to signal processing and analysis. Examples of signal processing demand in medical research includes medical imaging such as sonograms, MRIs, CT scans, electrocardiograms, electroencephalograms, etc. as well as electrocardiograms. The amount of physiological data being collected is presently enormous, yet most medical research facilities do not have the ability to properly process, store, and subsequently analyze the data, particularly when the analysis requires comparison to other studies and databases. Such comparisons, when properly performed, may lead to more accurate diagnoses. In most cases, individual research facilities do not have access to databases, often because the database cost is prohibitive. In many instances, the costs of database storage and maintenance (searching, etc.) are also limiting factors.

There is currently not an efficient method or system that allows facilities such as medical research facilities to obtain reliable analysis of their data.

What is needed is an effective method or system that provides accurate analysis and classification of signals that benefits from comparison to database statistics.

### SUMMARY OF THE INVENTION

It is an aspect of the present invention to provide methods and systems for allowing remote analysis of signals. In one embodiment of the invention, the remote analysis is performed through a communications network such as the internet. In one embodiment, the analysis may be applied to any physiological data that may be collected from a mammalian creature.

It is another aspect of the invention to provide methods and systems wherein an application service provider (ASP) may provide an application to a individual or entity, including for example, a medical research facility, hereinafter referred to as a subscriber, wherein the application may be loaded onto a subscriber computer that may be connected to the internet. In an embodiment, the medical research facility may be one of many institutions studying mammals, including genetically altered animals such as mice. In one embodiment, data may be collected from the mice as different drugs and other genetic mutations are imposed on the mouse by the subscriber. Such data may include blood pressure, respiratory rate, and electrocardiograms. In an embodiment, the application may provide a user interface or graphical user interface (GUI) to the subscriber for collecting the desired data. In one embodiment, the methods and systems herein may allow for the collection of signals, processing of signals, and further classification of signals to identify a genetic mutation.

It is an aspect of the invention to provide methods and systems wherein the application allows for the collection, classification, and transfer of data from the subscriber to a remote analysis location. In one embodiment, the data may be classified in terms of its type, and depending on the type or class, certain analysis options may be provided to the subscriber. For example, in an embodiment wherein electrocardiogram data is collected, the subscriber may be prompted with options to analyze the data for certain arrhythmias or other conditions, heart rates, etc., or the subscriber may be prompted with a menu from which the subscriber may select various parameters for measurement.

It is an aspect of the invention to allow the subscriber to indicate whether the subscriber desires data and results to be incorporated into a remote database. In yet another embodiment, the subscriber may identify a particular existing database that may form the basis for analysis. In an embodiment, the remote database may be one or multiple databases, physically or logically separated, that may be maintained by the ASP. Upon receiving data from a subscriber, the ASP may categorize the data and apply one or more of many signal processing algorithms. In an embodiment, the ASP may maintain a repository of certain signal processing techniques, for example, electrocardiogram signal processing algorithms. In one embodiment, the signal processing algorithms may be available as selections to the subscriber, and such subscriber selection may be transmitted with the data to the ASP for subsequent application of the algorithm.

It is an aspect of the present invention to compile databases of analyzed data from subscribers. In an embodiment, the databases may be utilized to generate rules, refine algorithms, and validate data. In one embodiment, subscribers may have the option of comparing their data against specific or generic database information. In an embodiment, a subscriber may indicate the intention to incorporate or not incorporate data into an existing database.

It is an aspect of the methods and systems disclosed herein to allow subscribers to specify parameters and other variables for specific algorithms, wherein such specified parameters and variables may be selectively applied at the remote location as determined by the subscriber.

It is an aspect of the invention for the ASP or other remote analysis engine, to provide the subscribers with analysis results. In an embodiment, analysis results may be data accompanied by graphical representations of data. In an embodiment, the graphical representations may be annotated. In yet another embodiment, specified parameters may be additionally annotated with “match” information that indicates similar information obtained through a search of existing databases as the remote location. In one embodiment, the “match” information may indicate a particular diagnosis. For example, in the example of collecting EKG signals from genetically altered mice, the analysis may provide a result that indicates the genetic alteration. In an embodiment, the subscriber may indicate which parameters or information should be matched. In an embodiment, identifiers associated with matched data may be provided to the subscriber.

Other objects and advantages of the invention will become obvious hereinafter in the specification and drawings.

### BRIEF DESCRIPTION OF THE DRAWINGS

A more complete understanding of the invention and many of the attendant advantages thereto will be readily appreciated as the same becomes better understood by reference to the following detailed description when considered in conjunction with the accompanying drawings, wherein like reference numerals refer to like parts and wherein:

FIG. 1 is an architectural block diagram of a system practicing the principles of the invention as disclosed herein;

FIG. 2 is a photograph of a sample subscriber collecting signal data in accordance with the system of FIG. 1;

FIG. 3 is a photograph of a signal collection system in accordance with the system of FIGS. 1 and 2;

FIG. 4 is a photograph of signal data and subscriber options being received and analyzed at a location remote from the subscriber, in accordance with the system of FIG. 1; and,

FIG. 5 is a photograph of the subscriber receiving the analysis results of FIG. 4.

### DESCRIPTION OF ILLUSTRATED EMBODIMENTS

To provide an overall understanding of the invention, certain illustrative embodiments will now be described; however, it will be understood by one of ordinary skill in the art that the systems described herein can be adapted and modified to provide systems for other suitable applications and that other additions and modifications can be made to the invention without departing from the scope hereof.

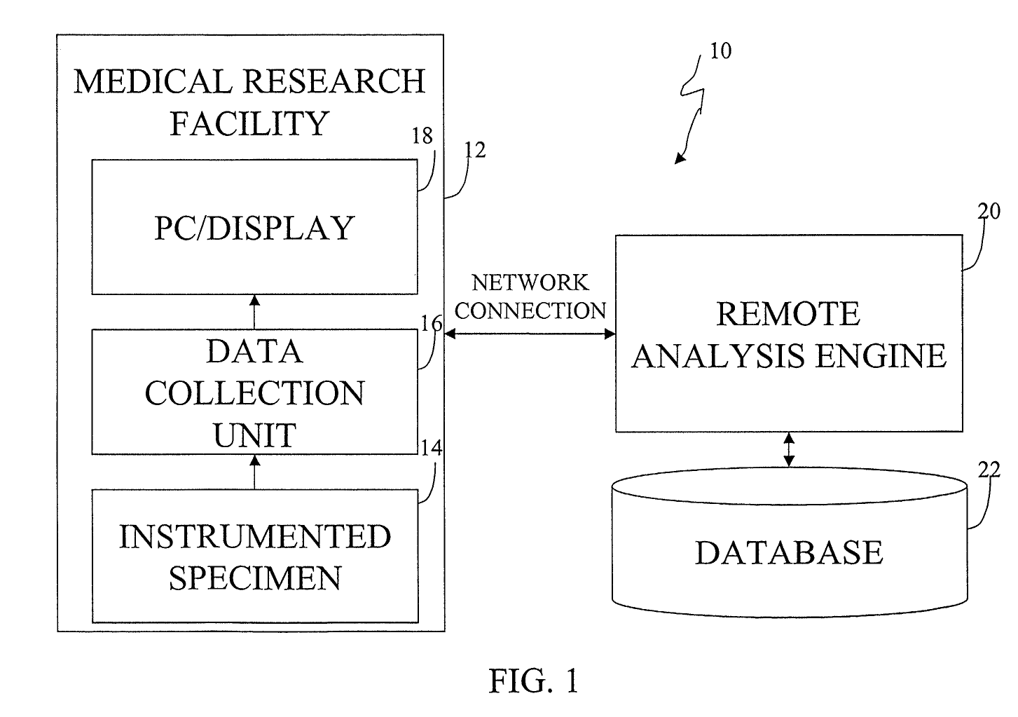

Referring now to FIG. 1, there is shown a system 10 that practices the principles of the invention, although those with ordinary skill in the art will recognize that the system 10 as presented is merely illustrative, and any division of functionality, unless explicitly stated otherwise, is merely for convenience in demonstrating the invention. In the system of FIG. 1 10, the application is a medical research facility 12, although the methods and systems disclosed herein may be applied to any signal analysis or processing application as described herein. In the illustrated embodiment, the medical facility 12 may routinely measure electrocardiograms (EKGS) of mice, otherwise indicated as the instrumented specimen 14, although such an example is merely for illustrative purposes, and the invention can be practiced using any source of signals, living or inanimate. Furthermore, the signals may be any electrically measured signals and are not limited to the EKG signals of the FIG. 1 illustrative system 10.

In the FIG. 1 system 10, the EKG signals from the mouse 14 are recorded by a data collection unit 16 that may include an analog-to-digital converter, a filter, gain control, etc., as is typical of data acquisition or collection units 16, and the invention herein is not limited by the components or functionality of the data collection unit 16 beyond its ability to acquire signals from the illustrative specimen 14 and convert such signals to digital form as required by the methods and systems as described herein. In the FIG. 1 system 10, the signals are transmitted to a personal computer (PC) 18 that maintains a display for allowing a PC user to view the signals from the data collection unit 16.

In one embodiment 10, the data collection unit 16 and PC 18 may be incorporated into a single unit with a data acquisition card loaded into a PC PCI slot and otherwise integrated with a typical standalone PC system that includes a hard-drive, CD ROM or DVD, microphone, soundcard, graphics card, keyboard, control mouse, display, and other peripherals and components typical of a standard PC.

In the illustrated system 10, the medical facility 12 shall hereinafter be referred to as a subscriber as the medical facility PC 18 includes an application that is provided according to the invention herein, to interface with the data collection unit 16. In the illustrated embodiment 10, the application includes a graphical user interface (GUI) that provides the PC user with graphical displays of the signals acquired by the data collection unit 16. Such a GUI may allow the user to select and deselect signals or waveforms or portions thereof, to save such waveforms or portions thereof, and otherwise designate specific waveforms or portions thereof for analysis, recall, etc. In the illustrated embodiment 10, the application GUI also allows the user to identify signal specifics including the type or source of signals collected (e.g., periodic, non-periodic, EKG, etc.).

In one embodiment, the user may specify the algorithm(s) that may be applied to the signals to analyze the signals. The algorithm selection may be further dependent upon a signal type provided by the user. For example, some algorithms may be specific to particular signal classes (periodic, non-periodic, etc.) or signal sources (electrocardiogram, etc.), while other algorithms may be applied to all signal types. Additionally, depending upon the choice of algorithm, specific parameters may be entered by the user for selective application to the signals. In one embodiment, several algorithms may be specified and associated parameters selected.

In one embodiment, the user may also specify whether the signals provided and analysis related thereto may be stored as part of a database. In the illustrated embodiment 10, the user may further specify whether the signals should be analyzed with respect to a particular database. In the illustrated embodiment 10, the user may indicate whether the signals should be classified according to a genetic mutation.

In one embodiment, the user may select the signals for processing, the signal type, the processing algorithm(s) and associated parameters, and database parameters, and cause the transmission of such information to a remote location that includes a remote analysis engine 20. In another embodiment, such data collection and transmission may be performed automatically by pre-configuring parameters and scheduling the transmission of data at specified intervals.

In the illustrated embodiment 10, the remote analysis engine 20 is connected to the PC 18 through the internet using standard internet connectivity equipment and software, although the invention herein is not limited to the network connection, and a local network or other networking configuration may be substituted without departing from the scope of the invention. In some embodiments, the remote analysis engine 20 may be collocated with the PC 18.

In the illustrated embodiment, the remote analysis engine 20 is a conventional PC with an associated executable program contained therein for receiving and interpreting information from the subscriber PC 18. The executable program further includes instructions for executing the appropriate signal processing algorithms in accordance with the information and instructions received from the subscriber PC 18. In the FIG. 1 system 10, the remote analysis engine 20 is collocated with a database 22 that may be a separate device from the remote analysis engine 20, or incorporated within the remote analysis engine 20, without departing from the scope of the invention. Additionally, although the FIG. 1 system indicates a single database 22, the invention herein is not limited by the number of databases, the physical or logical partitioning thereof, or the database structure, management, or querying formats.

In one embodiment, the remote analysis engine 20 may utilize the database 22 to perform analysis or store the analysis results. The remote analysis engine 20 may further maintain executable programs for searching, maintaining, and otherwise managing the database 22, including incorporating new information into the database 22. In one embodiment, information from the database 22 may be utilized to train a neural network or other classification scheme for application to received signals. In such an embodiment, signals received for analysis may be processed and input to the neural network or other classifier for classification. In the illustrated embodiment 10 wherein genetic mice are presented, a neural network may be devised for each genetic mutation to allow identification of genetic mutation from received EKG signals. Those with ordinary skill in the art will recognize that the invention herein is not limited to the classification scheme, and any well-known classification scheme, including but not limited to Bayesian, Fuzzy logic, etc., may be utilized without departing from the scope of the invention.

In the illustrated system 10, the remote analysis engine 20 includes a display that provides a remote analysis engine user with the ability to view the analysis results, progress, etc., and to further annotate the results. Although in one embodiment, the remote analysis engine 20 may perform designated analysis without intervention from a user, in the illustrated system, the remote analysis engine 20 enables user intervention through a GUI that allows the user to further interpret the commands received from the subscriber PC 18. For example, the user may further perform database management, annotate waveforms in accordance with the desired analysis, and control the information between the subscriber PC 18 and the remote analysis engine 20.

In the illustrated system 10, once the remote analysis engine 20 completes the analysis of the received signals and performs such other operations (i.e., classification) as instructed by the commands received by the subscriber PC 18, the remote analysis engine 20 causes the transfer of the analysis results to the subscriber PC 18. In the FIG. 1 system, a remote analysis engine user may initiate the transfer of information to the subscriber PC 18, a subscriber PC user may allow the display of the analysis results in various formats that may include tables, text files, and graphical formats. In the illustrated system 10, the subscriber PC user may further annotate graphical results and otherwise edit the analysis.

Referring now to FIG. 2, there is shown a photograph of a sample subscriber collecting data in accordance with the system of FIG. 1, wherein the subscriber system collects electrocardiogram (EKG) data from mice.

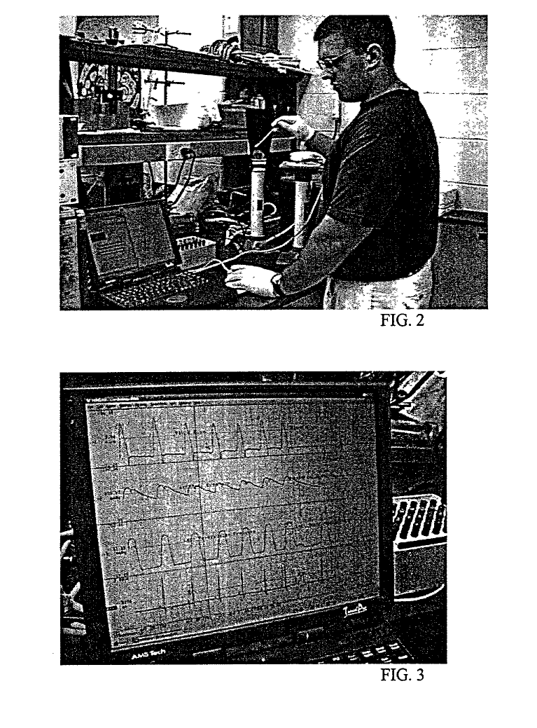

Referring now to FIG. 3, there is shown a photograph of the subscriber PC GUI indicating a signal acquisition and data collection from the EKG in accordance with the systems of FIGS. 1 and 2.

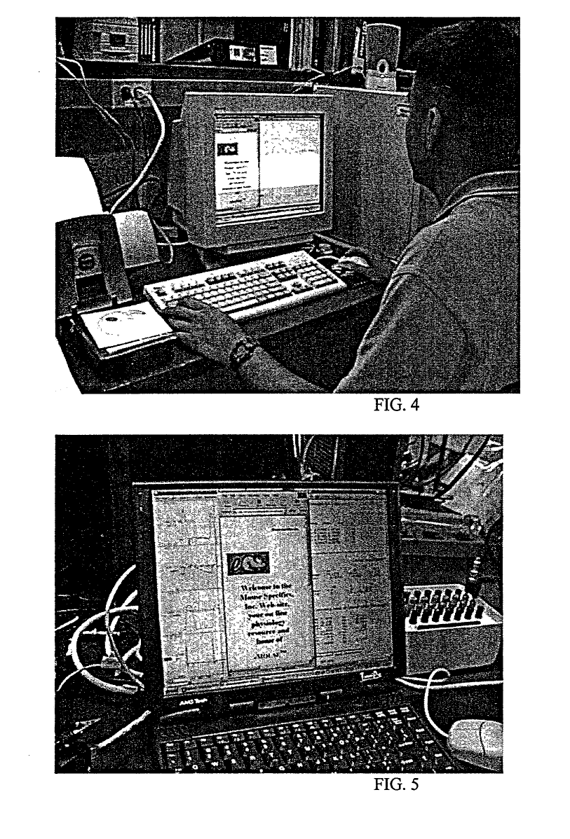

Referring now to FIG. 4, there is shown a photograph of EKG signal data and subscriber analysis options being received and analyzed at a remote location in accordance with the system of FIG. 1.

Referring to FIG. 5, there is shown a photograph of the subscriber receiving the EKG analysis results.

One advantage of the present invention over the prior art is that remote analysis of signals can be performed through a network connection using a suite of algorithms.

What has thus been described is methods and systems for remotely analyzing signals through a communications network. In one embodiment, the methods and systems may be adapted to a subscriber medical research facility wherein data is collected from samples for further analysis. The methods and systems provide a graphical user interface to allow the subscriber to collect data through a data acquisition system, classify the waveforms, select appropriate analysis algorithms and results, and further choose algorithm parameters. The data and all subscriber-entered options may be transmitted through a communications system to a remote analysis engine that may be coupled to a database. The remote analysis engine may analyze the data in accordance with the analysis options. In some embodiments, the analysis results may be obtained or further incorporated into the database. The analysis results may also be transmitted through the communications network, to the subscriber for further review and editing by the subscriber. In one embodiment, the communications network is the internet.

Although the present invention has been described relative to a specific embodiment thereof, it is not so limited. Obviously many modifications and variations of the present invention may become apparent in light of the above teachings. For example, although the system disclosed herein referred to medical research facilities and in particular, mice EKGs, the systems and methods are applicable to any signal processing and classification that may be performed remotely from a data collection unit.

Many additional changes in the details, materials, steps and arrangement of parts, herein described and illustrated to explain the nature of the invention, may be made by those skilled in the art within the principle and scope of the invention. Accordingly, it will be understood that the invention is not to be limited to the embodiments disclosed herein, may be practiced otherwise than specifically described, and is to be understood from the following claims, that are to be interpreted as broadly as allowed under the law.

What is claimed is:

1. Computer readable products disposed on a computer readable medium for analyzing signals on a first platform, wherein the signals are collected on a distinct second platform, and the first platform and the second platform are connected through a communications system, the products comprising instructions for causing a processor to
acquire signals for analysis,
display the signals to a subscriber user,
provide an interface to allow the subscriber user to, on the second platform, select at least one analysis algorithm,
transmit the signals and the selected algorithm to the first platform,
on the first platform, analyze the signals in accordance with the selected algorithm,
interface the second platform to a database for data analysis,
classify the signals;
transmit analysis and classification results from the first platform to the second platform, and
allow editing and display of the analysis and classification results on the second platform.

2. A computer readable product according to claim 1, wherein the instructions to acquire signals for analysis further comprise instructions to acquire signals of an electrocardiogram.

3. A computer readable product according to claim 1, wherein the instructions to classify the signals further comprise instructions to categorize a genetic condition.

4. A computer readable product according to claim 3, wherein the instructions to categorize further comprise instructions to implement a neural network.
